(19) United States
(12) Patent Application Publication
(10) Pub. No.: US 2009/0140891 A1
(43) Pub. Date: Jun. 4, 2009

(54) LIGHT-SENSITIVE KEYBOARD

(75) Inventors: Ciro Ragusa, Lucera (IT); Roberto Ragusa, Lucera (IT)

Correspondence Address: IBM CORP. (AUSTIN), C/O NELSON AND NELSON, 2984 E. EVERGREEN AVE., SALT LAKE CITY, UT, 84109, US

(73) Assignee: International Business Machines Corporation, Armonk, NY (US)

(21) Appl. No.: 12/249,043

(22) Filed: Oct. 10, 2008

(30) Foreign Application Priority Data
Dec. 4, 2007 (EP) EP07122299

(51) Int. Cl. H03M 11/00

(52) U.S. Cl. 341/31

(57) ABSTRACT

Certain embodiments of the invention provide a keyboard apparatus that may include an array of keys including a modifier key associated with one or more modifiable keys. Each modifiable key may include a main label and a secondary label. The secondary label may represent a function accessible by activating the modifiable key in combination with the modifier key. Further, the secondary label may include a light-reactive material visible only upon irradiation with light having a certain predefined wavelength. A light-emitting device may direct light having the predefined wavelength towards the array. A control element, however, may activate the light-emitting device only upon activation of the modifier key. In this manner, the light-emitting device may selectively illuminate the secondary label to assist a user in identifying and accessing the same.

### BACKGROUND OF THE INVENTION

### Description of the Related Art

Keyboards are generally included with computer systems to enable user interaction with the computer.

Standard keyboards are generally provided with an array of keys, including modifiable keys on which two or more labels, such as alphanumeric characters or symbols, are printed or edged. A main label among all the labels printed on a modifiable key is directly accessible by simply pressing the modifiable key. To access secondary labels printed on the same modifiable key, the user must press the modifiable key in combination with a dedicated modifier key, such as the “Shift,” “NumLock,” or “Alt” key.

One type of modifier key, such as “Shift” or “Alt” keys, may be pressed simultaneously with the modifiable key to activate the desired secondary label. Another type of modifier key, such as the “NumLock” key, must be pressed prior to pressing the modifiable key, thereby changing the state of the keyboard. The user may then press the modifiable key, without maintaining pressure on the modifier key, to access the second label. After activating the secondary label, the user must again press the modifier key to deactivate the modifier key.

The labels on a modifiable key are generally arranged in such a way that the user must guess which modifier key should be pressed to activate functions represented by different labels on the same key. In some keyboards, the label that is directly accessible by pressing the modifiable key alone has a normal size, while secondary labels requiring simultaneous pressure of a modifier key have a smaller size. As a result, the keyboard may appear cluttered, having several labels on multiple keys.

### SUMMARY OF THE INVENTION

Embodiments of the invention have been developed to assist a user in identifying accessible labels on keys.

A keyboard apparatus in accordance with certain embodiments of the invention may include an array of keys that includes a modifier key associated with one or more modifiable keys. Each modifiable key may include a main label and a secondary label. The secondary label may represent a function accessible by activating the modifiable key in combination with the modifier key. Further, the secondary label may include a light-reactive material that becomes visible only upon irradiation with light having a certain predefined wavelength.

A light-emitting device may direct light having the predefined wavelength towards the array. A control element may activate the light-emitting device upon activation of the modifier key. In this manner, the light-emitting device may selectively illuminate the secondary label to assist a user in identifying and accessing the same.

A corresponding system is also disclosed and claimed herein.

### BRIEF DESCRIPTION OF THE DRAWINGS

In order that the disclosure will be readily understood, a more particular description of embodiments of the invention briefly described above will be rendered by reference to specific embodiments illustrated in the appended drawings. Understanding that these drawings depict only typical embodiments of the invention and are not therefore to be considered limiting of its scope, embodiments of the invention will be described and explained with additional specificity and detail through use of the accompanying drawings, in which:

FIG. 1 is a schematic view of a computer system in accordance with certain embodiments of the invention;

FIG. 2 is a perspective view of a modifiable key in accordance with certain embodiments;

FIG. 3 is a perspective view of a portable computer in accordance with an embodiment of the invention;

FIG. 4 is a partial view of the portable computer of FIG. 3, showing a light-emitting device in accordance with certain embodiments of the invention;

FIG. 5 is a block diagram showing various operating components of a control element in accordance with embodiments of the invention;

FIG. 6 is a schematic diagram of logic circuitry implemented in a control element in accordance with certain embodiments of the invention;

FIGS. 7 and 8 are perspective views of the modifiable key of FIG. 2 showing different states;

FIG. 9 is a partial view of the portable computer of FIG. 3, showing an alternative embodiment of a light-emitting device;

FIG. 10 is a perspective view of a modifiable key in accordance with the alternative embodiment of FIG. 9;

FIG. 11 is a partial view of one embodiment of a keyboard in accordance with the invention, showing alternative positioning of the light-emitting device; and

FIG. 12 is a schematic diagram showing a side view of the keyboard represented in FIG. 11.

### DETAILED DESCRIPTION OF THE INVENTION

It will be readily understood that the components of embodiments of the present invention, as generally described and illustrated in the Figures herein, may be arranged and designed in a wide variety of different configurations. Thus, the following more detailed description of the embodiments of the systems and methods of the present invention, as represented in the Figures, is not intended to limit the scope of the disclosure, as claimed, but is merely representative of selected embodiments of the invention.

Reference throughout this specification to “one embodiment,” “an embodiment,” or similar language means that a particular feature, structure, or characteristic described in connection with the embodiment may be included in at least one embodiment of the present invention. Thus, appearances of the phrases “in one embodiment” or “in an embodiment” in various places throughout this specification are not necessarily all referring to the same embodiment.

Furthermore, the described features, structures, or characteristics may be combined in any suitable manner in one or more embodiments. One skilled in the relevant art will recognize, however, that embodiments of the invention can be practiced without one or more of the specific details, or with other methods, components, etc. In other instances, well-known structures, or operations are not shown or described in detail to avoid obscuring aspects of the disclosure.

The illustrated embodiments of the invention will be best understood by reference to the drawings, wherein like parts are designated by like numerals throughout. The following description is intended only by way of example, and simply illustrates certain selected embodiments of the invention that are consistent with the disclosure as claimed herein.

Referring now to FIG. 1, a computer system 100 in accordance with embodiments of the invention may include a computer 10 and a keyboard unit 11. The hardware of the computer 10 may include a central processing unit (CPU), which typically stores and executes applications installed on the computer system, and displays such via a monitor. The monitor may be operably connected to the CPU to display the graphic user interface of executing applications, and to echo or display user input.

The keyboard unit 11 may be connected to the CPU to allow user interaction with the computer 10. The keyboard unit 11 may include a keyboard interface 2 provided with an array of keys 20. The user may operate the keyboard interface 2 to control applications running on the computer 10, and to provide input data to those applications. More specifically, the computer 10 may allow feedback from the keyboard unit 11 to be dynamically displayed on a monitor, thereby indicating which keys 20 of the keyboard have been or are being pressed.

The computer 10 may further include a program memory, a working memory, such as a RAM of any suitable technology, a mass memory, such as one or more hard disks, and a network interface device. The network interface device may be connected to a communication medium to enable communication with other computers. Data may be exchanged between these components through a bus system.

The computer system 100 described above is, of course, only one example of a suitable computing environment, and is not intended to limit the scope of embodiments of the invention in any way.

The keyboard unit 11 may further include a microprocessor 3, and a memory 4 connected thereto. The memory may include, for example, read-only memory.

The microprocessor 3 may be provided to detect pressed keys by scanning the keyboard interface 2 and analyzing the status of each key. When a key is pressed, the microprocessor 3 may generate a scan signal corresponding to the pressed key, and retrieve the key code corresponding to the pressed key from a key code table stored in memory 4. The microprocessor 3 may then transmits the resulting key code to the computer 10.

The key code table in memory 4 may store the key code represented by each individual key 20 on the keyboard interface 2. Although the memory 4 is represented as separated from the microprocessor 3, one skilled in the art will recognize that, alternatively, the memory 4 may be incorporated into the microprocessor 3.

The keyboard interface 2 may be based on key layouts such as the QWERTY layout or the DVORAK layout. It should be noted, however, that the invention herein is not limited to any particular key layout. Rather, embodiments of the present invention may be implemented in connection with any type of keyboard, including keyboards integrated with notebook computers, personal digital assistants (“PDAs”), or cell phones.

In a standard QWERTY keyboard layout, the keyboard interface 2 generally includes alphanumeric keys for each letter of the alphabet and the numerals 0-9; special keys such as a PrintScreen key 204, a ScrollLock key 205, a Pause key 206, an Enter key 219, and a spacebar 213; function keys 201, such as “F1” to “F12”; and indicators to indicate the status of the NumLock key 207, the CapsLock key 217 and the ScrollLock key 205. Indicators may include a NumLock indicator light 208, a CapsLock indicator light 209 and a ScrollLock indicator light 210, each incorporating a light emission diode (“LED”). A standard QWERTY keyboard interface 2 may also include modifier keys, such as a NumLock key 207, control (“Ctrl”) keys 211, Alternate (“Alt”) keys 212, a CapsLock key 217, and Shift keys 216.

As used herein and in the appended claims, the term “modifier keys” is used to describe a group of keys that may be pressed in combination with another key or keys to increase the number of keyboard functions. A key having a function that may be altered by a modifier key is referred to herein as a “modifiable key.” One type of modifier keys includes keys that must be pressed simultaneously with one or more modifiable keys such as a “shift,” “ctrl,” or “alt” key. Another type of modifier keys includes keys that must be activated prior to pressing a modifiable key. This second type of modifier keys function to change the keyboard state, such as a “NumLock” key. Second-type modifier keys may be deactivated by re-pressing the modifier key.

Each key 20 may include an actuator mounted on a keyboard base pan. The actuators of the keys 20 may cooperate with a signal generation circuitry that transmits an appropriate signal when a key is depressed. In an exemplary embodiment, the keys 20 may be formed as separate structural elements. However, embodiments of the invention are not limited to this exemplary keyboard configuration. Further, embodiments of the invention are not limited to depressible keys but may include any type of key that can be activated by user contact.

Each modifiable key 20 of the keyboard interface 2 may include a main label and one or more secondary labels printed or edged on its top surface. If the keyboard status has not been changed by activating a second-type modifier key, the function associated with the main label may be accessed by simply pressing the key 20. Functions associated with secondary labels, on the other hand, may be accessed only by pressing the modifiable key in combination with a modifier key.

As used herein, the term “label” is intended to encompass a symbol or other figure that may be entered by the user. Examples of labels include alphabetic characters, such as from the Roman, Arabic, Hebrew, or Greek alphabets, for example. A label may also be a numeral, a punctuation mark, or one of the various symbols that are commonly utilized in typing, such as #, %, &, or @, for example. In addition, a label may be one of the various symbols utilized in Asian languages, such as the Chinese or Japanese languages.

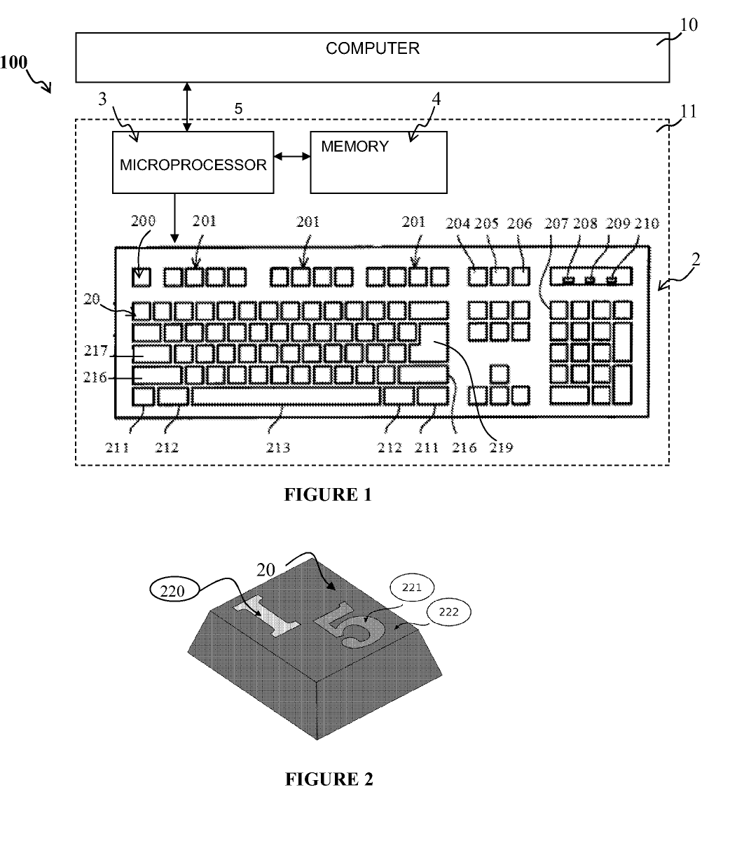

FIG. 2 depicts an exemplary modifiable key 20 according to some embodiments of the invention. As shown, the key 20 may include a main label 220, corresponding to alphabetic character “I”, and a secondary label 221, corresponding to numeral “5”. The function associated with the main label 220 may be accessed by pressing the key 20 alone, if no other modifier key has been activated. The secondary label 221 may be accessed by activating a modifier key, such as the NumLock modifier key 207, and then pressing the modifiable key 20. The labels 220 and 221 may be arranged on the top surface 222 of the modifiable key as desired.

In one embodiment, the main label 220 may be visible under normal lighting conditions, while the secondary label 221 may be invisible under such conditions. When the secondary label 221 is activated (e.g. by pressing a predefined modifier key in combination with the key 20), the secondary label 221 may be illuminated by light having specific spectral components. For example, the secondary label 221 may be illuminated by ultraviolet light emitted from a light-emitting device. This may cause the secondary label 221 to become much more visible than the main label 220.

More specifically, the secondary label 221 may be formed at least in part from a material that is reactive to light, in particular to light from the ultraviolet (“UV”) portion of the electromagnetic spectrum. Accordingly, the secondary label 221 may form somewhat of an ultraviolet-sensitive label that will emit light from the visible portion of the electromagnetic spectrum while it is irradiated with UV light from the light-emitting device 6. The secondary label 221 may stop emitting visible light when the radiation from the light-emitting device is removed. The main label 220 may be formed from a conventional ink that has no reactive property when irradiated by a light-emitting device 6.

According to one embodiment, one or more light-emitting devices 6 may be provided to only make visible the secondary labels 221 when the corresponding functions have been activated, by pressing an associated modifier key, for example. The secondary labels 221 may be substantially invisible when the corresponding functions are not activated.

In this manner, embodiments of the invention manage the appearance of multiple labels printed on a single modifiable key 20. The invention also improves the general appearance of the keyboard by only making visible the secondary labels that are activated.

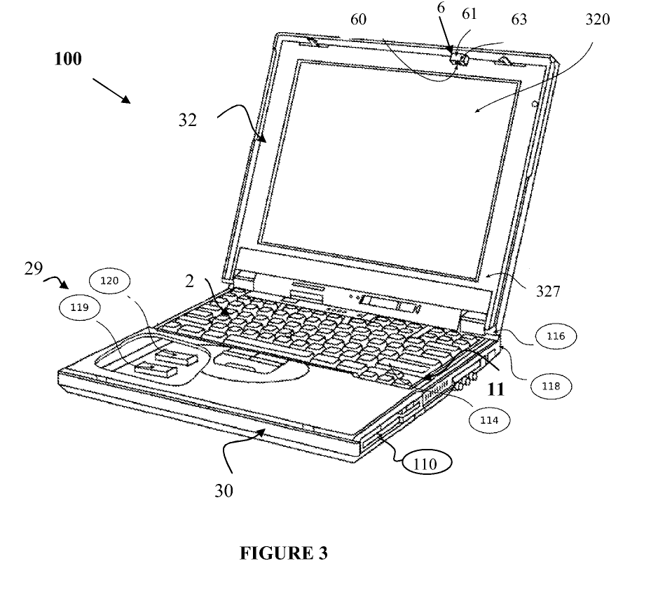

FIG. 3 depicts an exemplary embodiment of the invention implemented in a portable computer system 100. According to this embodiment, the computer system 100 includes a base housing 30 and a display housing 32 pivotably connected to the base housing 30. The base housing 30 may include electronic connections for external components such as a USB plug. The base housing 30 may also include electronic modules such as a CD-ROM drive module 110. The base housing 30 may further include a keyboard unit 11 having a keyboard interface 2 as described above with reference to FIG. 1.

A display housing 32 may be provided to support a display 320, and to protect the keyboard interface 2 when the portable computer is closed.

The computer system 100 further may include a number of components that are not shown, such as the operating components described above for the computer part 10, and a number of other conventional components such as, for example, audio and video cards, headphone and microphone ports, serial, parallel and USB ports, mouse ports, operating system, and various application programs.

According to this embodiment of the invention, an ultraviolet (“UV”) light-emitting device 6 may be provided to irradiate the labels of the modifiable keys. The UV light-emitting device 6 may include a UV LED (“Light-emitting Diode”) 63 arranged inside a LED support 61. In one embodiment, such as that discussed above with reference to FIG. 3, the UV light-emitting device 6 may be arranged at the upper part of the display housing 32, above the display 320. One skilled in the art will understand, however, that the invention is not limited to such an arrangement, and that embodiments of the present invention encompass any arrangement contemplated by those in the art. For example, the UV LED 63 may be arranged at other suitable positions of the display housing 32, or may be embedded in the keyboard unit 11.

The UV light-emitting device 6 may be connected to control element 29 embedded in the keyboard unit 11, for example, for controlling the UV light-emitting device state. The control element 29 may include software or hardware logic, such as a control circuit 119 that may provide or interrupt a LED power supply 120 to activate or deactivate the UV light-emitting device 6.

To control activation of the UV light-emitting device 6, the control element 29 may take into account events such as activation of a modifier key by the user, activation of a modifier key by a software application, and other information, such as the open or closed state of the portable computer 100.

More specifically, the control element 29 may receive information regarding activation of a modifier key by the user or by a software application, for example. The control element 29 may be adapted to activate the UV light-emitting device 6 in response to the reception of such information. When the UV light-emitting device 6 is activated, it irradiates an area of the keyboard interface 2, which makes visible the secondary labels associated with that modifier key in the area. For instance, in one embodiment, activation of the “Numlock” key causes the numbers from 0 to 9, as well as some mathematical signs of the keyboard interface 2 to become visible, so long as the UV light-emitting device 6 illuminates substantially the entire surface of the keyboard interface 2.

The control element 29 may further receive information from a switch 116 regarding the open or closed state of the portable computer 100. The switch 116 may be adapted to detect whether the computer system 10 is in a open or closed state. In FIG. 3, the switch 116 is represented at the bottom right hand corner. In selected embodiments, the switch 116 may be placed between the display housing 32 and the base housing 30 to detect whether the display housing 32 is open or closed. An associated signal may then be provided to the control element 29. The switch 116 may ensure that the UV light-emitting device 6 will not be activated when the computer is closed, thereby resulting in power savings.

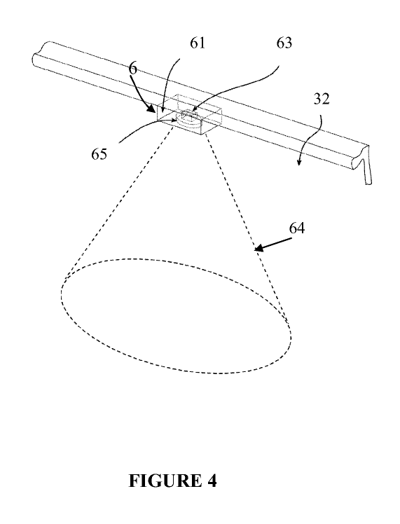

FIG. 4 depicts in more detail the UV light-emitting device 6 in accordance with selected embodiments of the invention. As shown, the LED support 61 may be delimited by a lower transparent wall 65, through which the UV LED 63 may provide a light beam 64 to illuminate an area of the keyboard interface 2.

The secondary labels of a key may be formed in a variety of ways. According to one embodiment of the invention, each secondary label may be formed on the top surface 222 of a key 20 in the shape of the intended character, word or symbol, using a material that becomes visible when irradiated by the UV light-emitting device 6.

The top surface 222 of the key 20 may be composed, at least in part, of an opaque substrate. The opaqueness of the key may obviate the need for a Phosphor-coated label disposed inside the key with added complexity and expense. Different materials may be used for the main label and the secondary labels of a particular modifiable key. In the exemplary key of FIG. 2, for instance, two different inks may be used for each of the labels 220 and 221 representing the characters “I” and “5.” The main label 220 in particular may be formed from a conventional ink that does not react to UV light.

The secondary label 221 may be formed by depositing a layer of UV-sensitive ink on the top surface 222 of the key 20, in the shape of the intended character, word or symbol. When the key is irradiated with UV light from the UV light-emitting device 6, the ink may reflect the light, thereby shifting it into the visible range. Embodiments of the invention may use as many different inks or materials as needed to distinguish between secondary labels printed on a particular key 20.

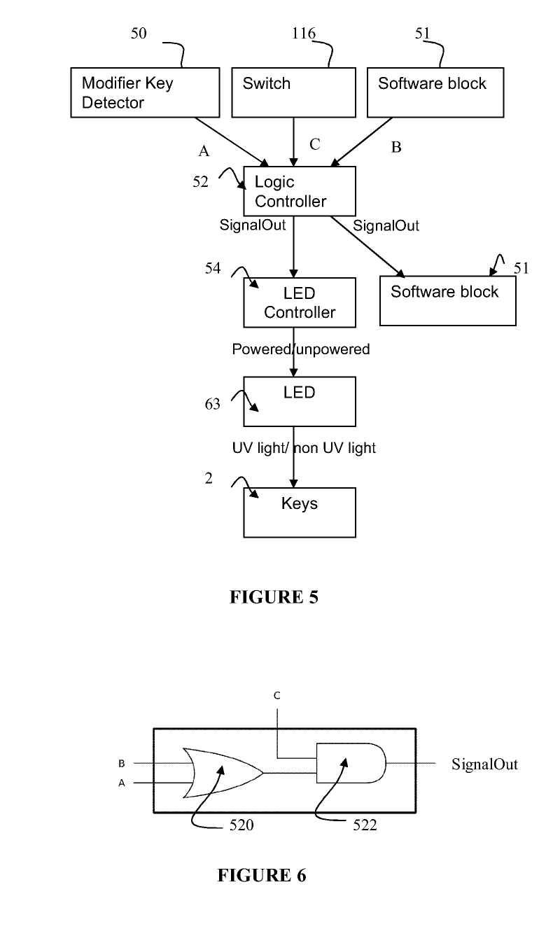

FIG. 5 is a block diagram illustrating exemplary functional blocks of the control element 29 for controlling the light-emitting device 6 in one embodiment of the invention. The control element 29 may receive a signal “A” from a Modifier Key block 50 that indicates whether a modifier key (e.g. Numlock, CapsLock, Alt, Shift, AltGr keys) is active (value “one”) or inactive (value “zero”). This may allow mechanical interaction between the user and the light-emitting device 6 through the keyboard.

The control element 29 may further receive a signal “B” from a software block 51. A signal B may be received from the software block 51, without any manual intervention by the user. For example, a signal B may be received in response to a request by a software application for input associated with a secondary label, such as a numeric input. The software application may then automatically enable the corresponding modifier key function, in this example the NumLock function, by generating a “one” value for the input signal B. The signal B may be received by the control element 29, without any manual intervention by the user, to activate the LED 63 in response to a software application request. For example, the software block 51 may send a “one” signal for activation of the UV-emitting device 6, and a “zero” signal otherwise.

The control element 29 may further receive a signal “C” from the switch 116. The switch 116 may send a “zero” signal if the cover is closed, and a “one” signal if the cover is open.

In some embodiments, the control element 29 may further comprise a logic controller 52 for processing the signals A, B and C received from the blocks 50, 116 and 51. According to one embodiment of the invention, the logic controller 52 may combine the signals A and B with an OR logic, and then combine the result thus obtained with signal C with a AND logic. The resulting output “SignalOut” may have a “zero” value or a “one” value, which may be used to control the LED 63. Specifically, if SignalOut has a zero value, the LED 63 may not be activated. If SignalOut has a one value, the UV LED 63 may be activated. According to this embodiment of the invention, if the switch 116 detects a closed state (e.g., signal C has a zero value), the LED 63 may always be switched off, thereby preventing unnecessary power consumption. Conversely, if the switch 116 detects an open state (e.g., signal C has a “one” value), then the LED 63 may only be activated if one or both signals A and B have a “one” value.

The Logic controller 52 may also send the SignalOut signal to the Software block 51 to inform the requesting software application(s) of the decision taken by the logic controller 52.

FIG. 6 illustrates operation of the logic controller 52 according to the embodiment described above. As shown, signals A and B may be inputted to an OR logic block 520, and the resulting signal from the OR block 520, in combination with signal C, may be inputted to a AND block 522, thereby providing the output SignalOut.

If a “one” value is obtained for the output signal SignalOut, then the control element 29 may switch the LED 63 on, causing the UV rays to reach the keys 20. As a result, the secondary labels of the keyboard interface 2 that are associated with the activated modifier may become visible and much more brilliant than the main labels printed or edged on the same modifiable keys.

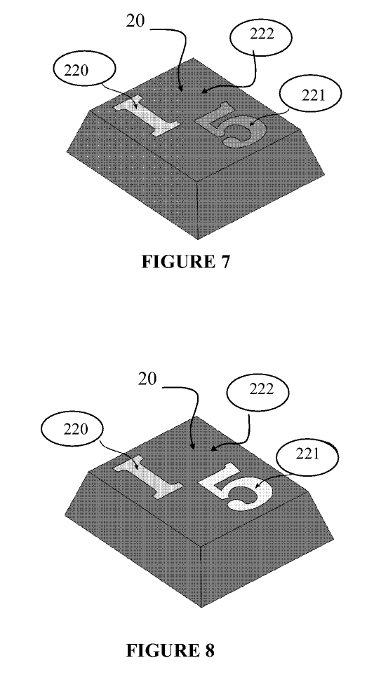

FIGS. 7 and 8 illustrate application of the above-described control method to the exemplary modifiable key 20 of FIG. 2. As shown in FIG. 7, for example, a key 20 may include a main label 220 and a secondary label 221 on the top surface 222 thereof. If the user presses the NumLock modifier key 207 to deactivate it, the main label 220 with the character “I” may be visible, while the secondary label 221 representing the numeric character “5” may remain invisible. In FIG. 7, for clarity, the secondary label 221 is shown darker in shade than the main label 220, rather than being completely invisible.

If the user then presses the NumLock modifier key to activate it, the control element may receive an input A from modifier Key block 50, indicating an active state for the NumLock modifier key. The control element 29 may then evaluate this input from the modifier key block, with the other inputs B and C as depicted in FIG. 5. If the result is such that the LED 63 is activated, then the secondary label 221 with the number “5” may become much more visible than the main label 220, as depicted by FIG. 8.

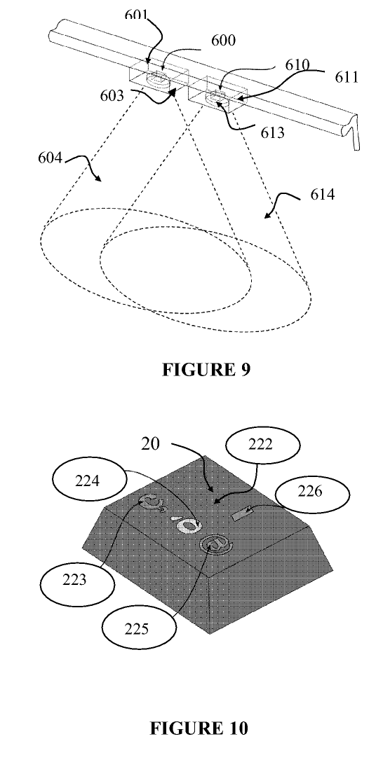

According to an alternative embodiment of the invention, illustrated in FIG. 9, the UV light-emitting device 6 may include a plurality of light-emitting devices. In particular, the UV light-emitting device 6 may include two light-emitting devices 600 and 610, each including a respective LED 603 and 613 supported by a respective LED support 601 and 611. Each light-emitting device 600 and 610 may provide a respective beam 604 and 614 directed towards a respective area of the keyboard interface 2. In the particular arrangement of FIG. 9, the light-emitting devices 600 and 610 are both arranged at the upper part of the display housing 32 so as to emit overlapping beams 604 and 614.

The light-emitting devices 600 and 610 may be provided to irradiate UV light of substantially similar wavelengths to obtain a more homogeneous distribution of the light across the keyboard interface 2. Alternatively, the light-emitting devices 600 and 610 may be provided to irradiate UV light of different wavelengths towards the keyboard interface 2, thereby activating one or more labels on a particular modifiable key 20.

In certain embodiments, a single key may be used for a plurality of secondary labels, as shown in FIG. 10. As shown in FIG. 10, for example, a key 20 may support a main label 224 for character “δ”, a first secondary label 223 for character “ç”, a second secondary label 225 for symbol “@” and a third secondary label 226 for dash symbol “-”. According to embodiments of the invention, the main label 224 may always be visible under normal lighting conditions (e.g. visible light illumination), while the secondary labels 223, 225 and 226 may remain invisible under normal light conditions. The secondary labels 223, 225 and 226 may be formed from materials that react to light of different wavelengths, such that each label reacts to a wavelength corresponding to a different light-emitting device. In the example of FIG. 10, three light-emitting devices, each emitting a different wavelength, may be required to separately activate the secondary labels 223, 225, 226.

According to certain embodiments, a light-emitting device may be provided in association with each modifier key (e.g. “NumLock”, “Shift”, etc.). Each secondary label accessed by a single modifier key (e.g. “NumLock”) may be made of a material that reacts to UV light having a wavelength substantially matching that emitted by the light-emitting device associated with the modifier key. The control element 29 may activate the light-emitting device associated with a modifier key in response to activation of that key by a user or software application. The light-emitting device may then irradiate an area of the keyboard interface, making visible the secondary labels associated with the activated modifier key in that area.

Embodiments of the invention thus ensure control of the light-emitting devices 600, 610 to selectively make all secondary labels associated with a modifierkey, e.g. the “Numlock” key, much more visible than main labels printed on the key in response to activation of the appropriate modifier key, e.g. “NumLock”. For example, activation of the “NumLock” key may result in activation of the light-emitting device adapted to make visible all numeric labels. Secondary labels associated with other modifier keys (e.g. “Alt” or “Shift” or “Ctrl”) may not react to the light beam, as they may constitute a material reactive to a wavelength other than that emitted by the activated light-emitting device.

In another embodiment of the invention, such as that illustrated in FIG. 11, a light-emitting device 620 may be placed inside a support 621, such as a mushroom-shaped support 621 located among modifiable keys 20.

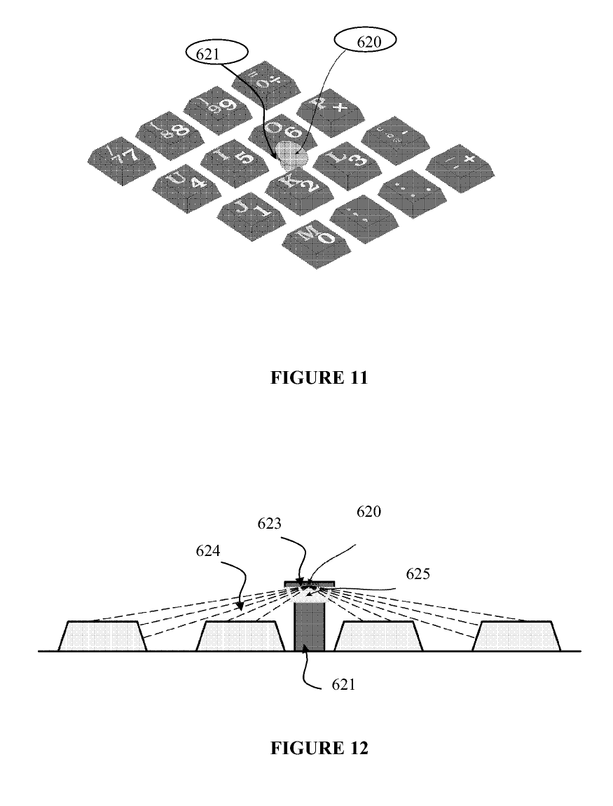

FIG. 12 is a schematic diagram representing an illumination path of a light-emitting device 620 according to one embodiment, such as that depicted in FIG. 11. The light-emitting device 620 may include a UV LED 623 within a support 621, and may include a transparent ring-shaped wall 625. The light beam 624 may be irradiated through the wall 625 around the support 621. This embodiment may be particularly suitable for standalone keyboards.

As demonstrated above, embodiments of the invention may enable dynamic modification of the keyboard appearance. More specifically, embodiments of the invention emphasize the appearance of a label on a modifiable key if the label has been activated by the user. This may allow a user to receive visible feedback upon activating a modifier key.

Embodiments of the invention further enable the keyboard to appear less cluttered to the user, thereby improving user interaction with the keyboard. As the user is better able to identify which function of a modifiable key is activated, he is less likely to make typing errors. Further, as the user may easily locate the activated labels of the keyboard, the typing operation may become faster.

Embodiments of the invention may also improve keyboard ergonomics without increasing the general encumbrance of the computer system 10.

Embodiments of the invention may include both hardware and software. In some embodiments, the invention may include a computer program product accessible from a computer-usable or computer-readable medium providing program code for use by or in connection with a computer or any instruction execution system. For the purposes of this description, a computer-usable or computer readable medium may include any apparatus able to contain, store, communicate, propagate, or transport the program for use by or in connection with the instruction execution system, apparatus, or device.

The foregoing is considered as illustrative only of the principles of embodiments of the invention. Further, since numerous modifications and changes may readily occur to those skilled in the art, it is not desired to limit the invention to the exact construction and operation shown and described. Accordingly, all suitable modifications and equivalents may be resorted to and are deemed to fall within the scope of the invention. For example, embodiments of the present invention have application in user interfaces other than those used in portable computers. Such applications may include desktop computers, electronic devices, automatic teller machines, printers and scanners. Further, embodiments of the invention are not limited to the number and arrangement of light-emitting devices described above for illustrative purposes.

1. A keyboard apparatus to assist a user in identifying accessible labels on keys, the apparatus comprising:
an array of keys comprising a modifier key associated with at least one modifiable key, each modifiable key comprising a main label and a secondary label, wherein the secondary label represents a function accessible by activating the modifiable key in combination with the modifier key, and wherein the secondary label comprises a light-reactive material visible only upon irradiation with light having a predefined wavelength;
a light-emitting device to direct light having the predefined wavelength towards the array; and
a control element to activate the light-emitting device to illuminate the secondary label upon activation of the modifier key.

2. The keyboard apparatus of claim 1, wherein a plurality of secondary labels associated with a single modifier key react to light having the same predefined wavelength.

3. The keyboard apparatus of claim 1, wherein the light-emitting device irradiates a predefined portion of the array.

4. The keyboard apparatus of claim 1, wherein the main label comprises a non-light-reactive material.

5. The keyboard apparatus of claim 1, wherein the control element further comprises a power supply actionable to control the light-emitting device.

6. The keyboard apparatus of claim 1, wherein the control element activates the light-emitting device in response to activation of the modifier key by a user.

7. The keyboard apparatus of claim 1, wherein the control element activates the light-emitting device in response to activation of the modifier key by a software application.

8. The keyboard apparatus of claim 1, wherein the light-emitting device comprises a light-emitting diode and a support for supporting the light-emitting diode.

9. The keyboard apparatus of claim 8, wherein the support comprises a lower transparent wall through which the light-emitting diode irradiates at least a portion of the array.

10. The keyboard apparatus of claim 8, wherein the support comprises a mushroom-like shape.

11. The keyboard apparatus of claim 1, wherein the light-emitting device is positioned above the array.

12. The keyboard apparatus of claim 1, wherein the light-emitting device is integrated with the array.

13. The keyboard apparatus of claim 8, wherein the support comprises a ring-shaped transparent wall through which the light-emitting diode irradiates at least a portion of the array.

14. The keyboard apparatus of claim 8, further comprising a plurality of the light-emitting devices, each light-emitting device emitting ultraviolet light having a different predefined wavelength.

15. The keyboard apparatus of claim 14, wherein the at least one modifiable key includes a plurality of secondary labels, each of the secondary labels reactive to a predefined wavelength emitted by exactly one of the plurality of light-emitting devices.

16. The keyboard apparatus of claim 1, wherein the light-emitting device emits ultraviolet light, and wherein the secondary label is reactive to ultraviolet light.

17. A system to assist a user in identifying accessible labels on keys, the system comprising:
a computer;
a keyboard operably coupled to the computer, the keyboard comprising:
an array of keys comprising a modifier key associated with at least one modifiable key, each modifiable key comprising a main label and a secondary label, wherein the secondary label represents a function accessible by activating the modifiable key in combination with the modifier key, and wherein the secondary label comprises a light-reactive material visible only upon irradiation with light having a predefined wavelength;
a light-emitting device to direct light having the predefined wavelength towards the array; and
a control element to activate the light-emitting device to illuminate the secondary label upon activation of the modifier key.

18. The computer system of claim 17, wherein the array of keys is integrated into a base housing.

19. (canceled)

20. The computer system of claim 19, further comprising a switch positioned between the base housing and the display housing to detect whether the display housing is in an open position or a closed position, wherein the control element deactivates the light-emitting device in response to the switch detecting the closed position.
